(19) United States
(12) Patent Application Publication
(10) Pub. No.: US 2003/0076167 A1
(43) Pub. Date: Apr. 24, 2003

(54) Multistage doherty amplifier

(76) Inventor: Richard Hellberg, Huddinge (SE)

Correspondence Address: NIXON & VANDERHYE P.C., 8th Floor, 1100 North Glebe Rd., Arlington, VA, 22201-4714, US

(21) Appl. No.: 10/310,065

(22) Filed: Dec. 5, 2002

Related U.S. Application Data
(63) Continuation of application No. PCT/SE01/01202, filed on May 30, 2001.

(30) Foreign Application Priority Data
Jun. 6, 2000 (SE) 0002148-5
Jul. 7, 2000 (SE) 0002584-1
Nov. 30, 2000 (SE) 0004420-6

(51) Int. Cl. H03F 3/68

(52) U.S. Cl. 330/124 R

(57) ABSTRACT

A multistage Doherty amplifier is provided with separate drive amplifiers (DR₄-DR₅) for individual power amplifier (PA₄-PA₅) and/or separate drive amplifiers (DR) for groups of power amplifiers (PA₁-PA₃). This makes it possible to make significant improvements in efficiency and linearity by optimizing the drive for the different power amplifiers and using only a minimum of drive power.

### TECHNICAL FIELD

The present invention relates to Doherty amplifiers, and especially to multistage Doherty amplifiers. The invention also relates to a transmitter including such an amplifier.

### BACKGROUND

In cellular base stations, satellite communications and other communications and broadcast systems, many radio frequency (RF) carriers, which are spread over a large bandwidth, are amplified simultaneously in the same power amplifier (PA). For the power amplifier this has the effect that the instantaneous transmit power will vary very widely and very rapidly. This is because the sum of many independent RF carriers (a multi-carrier signal) tends to have a large peak-to-average power ratio. It also tends to have a similar amplitude distribution as bandlimited Gaussian noise, which has a Rayleigh distribution.

The main difficulties in a power amplifier are efficiency and linearity. A conventional class B power amplifier exhibits maximum DC-to-RF power conversion efficiency when it delivers its peak power to the load. Since the quasi-Rayleigh distribution of amplitudes in the summed transmit signal has a large difference between the average power and the peak power, the overall efficiency when amplifying such a signal in a conventional class B amplifier is very low. For a quasi-Rayleigh distributed signal with a 10-dB peak-to-average power ratio, the efficiency of an ideal class B amplifier is only 28%. see [1].

The linearity of an RF power amplifier is usually characterized by its AM-AM (AM=amplitude modulation) and AM-PM (PM=phase modulation) distortion characteristics. Non-linearities manifest themselves as cross-mixing of different parts of the signal, leading to leakage of signal energy into unused channels. By restricting the signal to be transmitted to a smaller part of the total voltage swing, the linearity can be increased. However, this reduces the efficiency of the amplifier even further. The linearity of a power amplifier is also greatly reduced if the amplifier saturates (the output voltage is clipped). This means that it is not possible to increase efficiency by driving the amplifier into saturation, since the distortion would then reach unacceptable levels.

One way of increasing the efficiency of an RF power amplifier is to use a Doherty amplifier, see [1, 2, 3]. It uses in its basic form two amplifier stages, a main and an auxiliary amplifier. The output is connected to the auxiliary amplifier, and the main amplifier is connected to the output through an impedance-inverter, usually a quarter wavelength transmission line or an equivalent lumped network.

At low output levels only the main amplifier is active, and the auxiliary amplifier is shut off. In this region, the main amplifier sees a higher (transformed) load impedance than the impedance at peak power, which increases its efficiency in this region. When the output level climbs over the so-called transition point (usually at half the maximum output voltage), the auxiliary amplifier becomes active driving current into the load. Through the impedance-inverting action of the quarter-wave line this decreases the effective impedance at the output of the main amplifier, such that the main amplifier is kept at a constant (peak) voltage above the transition point. The result is a linear output power to input power relationship, but with a higher efficiency than a traditional amplifier.

The transition point can be shifted, so that the auxiliary amplifier kicks in at a lower or higher power level. This can be used for increasing efficiency for a specific type of signal or a specific power distribution. When the transition point is shifted, the power division between the amplifiers at peak power is shifted accordingly, and the average power loss in each amplifier is also changed. The latter effect depends also on the specific amplitude distribution.

The Doherty concept has been extended to multistage (i.e. more than two stages) variants, see [1, 4, 5]. This allows the efficiency to be kept high over a broader range of output power levels and varying amplitude distributions. Alternatively, the average efficiency for a specific amplitude distribution and a specific power level can be increased. Reference [4] should actually not be classified as a Doherty amplifier in strict terms, since it uses “unity amplifiers” which are switched off at low output power, and since the combining network also looks different from the typical Doherty output network. However, it has been included in the reference list due to its similarities with Doherty amplifiers.

Two problems associated with, or especially pronounced in, multistage Doherty amplifiers have been identified. These are the problem of low efficiency, if amplifiers (transistors) with limited gain are used, and the problem of poor linearity.

The low efficiency is caused by the excessive drive power that is needed if prior art multistage Doherty amplifier implementations are used. This problem is especially pronounced if the power amplifiers in the Doherty amplifier have low gain.

The poor linearity is caused by the fact that in the prior art multistage Doherty amplifiers, some of the amplifiers (all but the power amplifiers of the two top stages) are required to saturate at certain transition points and remain saturated above these transition points.

### SUMMARY

An object of the present invention is to provide a multistage Doherty amplifier, which retains most of the high efficiency even when low gain power amplifiers (transistors) are used.

Another object of the present invention is to reduce the distortion of a multistage Doherty amplifier.

A further object is a transmitter provided with such a Doherty amplifier

These objects are achieved in accordance with the attached claims.

Briefly, the present invention uses separate drive amplifiers for individual power amplifiers and/or groups of power amplifiers. This makes it possible to make significant improvements in efficiency and linearity by optimizing the drive for the different power amplifiers and using only a minimum of drive power. As an alternative, a shared drive amplifier and a power divider may be supplemented individual drive voltage limiters to at least some of the power amplifiers.

### BRIEF DESCRIPTION OF THE DRAWINGS

The invention, together with further objects and advantages thereof, may best be understood by making reference to the following description taken together with the accompanying drawings, in which:

FIG. 1 is a block diagram of a prior art multistage Doherty amplifier;

FIG. 2 is a block diagram of a part of a multistage Doherty amplifier;

FIG. 3 is a block diagram of an exemplary embodiment of a power amplifier stage of a multistage Doherty amplifier in accordance with the present invention;

FIG. 4 is a block diagram of another exemplary embodiment of a power amplifier stage of a multistage Doherty amplifier in accordance with the present invention;

FIG. 5 is a block diagram of a further exemplary embodiment of a power amplifier stage of a multistage Doherty amplifier in accordance with the present invention;

FIG. 6 is a block diagram of still another exemplary embodiment of a power amplifier stage of a multistage Doherty amplifier in accordance with the present invention;

FIG. 7 is a diagram illustrating the relationship between normalized drive voltage and normalized output voltage of an exemplary embodiment of the multistage Doherty amplifier in accordance with the present invention;

FIG. 8 is a diagram similar to FIG. 7 illustrating the relationship between normalized drive voltage and normalized output voltage of a prior art multistage Doherty amplifier;

FIG. 9 is a block diagram of an exemplary embodiment of a multistage Doherty amplifier in accordance with the present invention;

FIG. 10 is a diagram illustrating attenuation functions that are suitable for the Doherty amplifier embodiment of FIG. 9;

FIG. 11 is a diagram comparing the total drive amplifier DC loss of the prior art and the present invention;

FIG. 12 is a diagram comparing the efficiency of the prior art and the present invention;

FIG. 13 is a diagram illustrating the normalized load resistance of the Doherty amplifier embodiment of FIG. 9;

FIG. 14 is a block diagram of another exemplary embodiment of a multistage Doherty amplifier in accordance with the present invention; and

FIG. 15 is a block diagram of still another exemplary embodiment of a multistage Doherty amplifier in accordance with the present invention.

### DETAILED DESCRIPTION

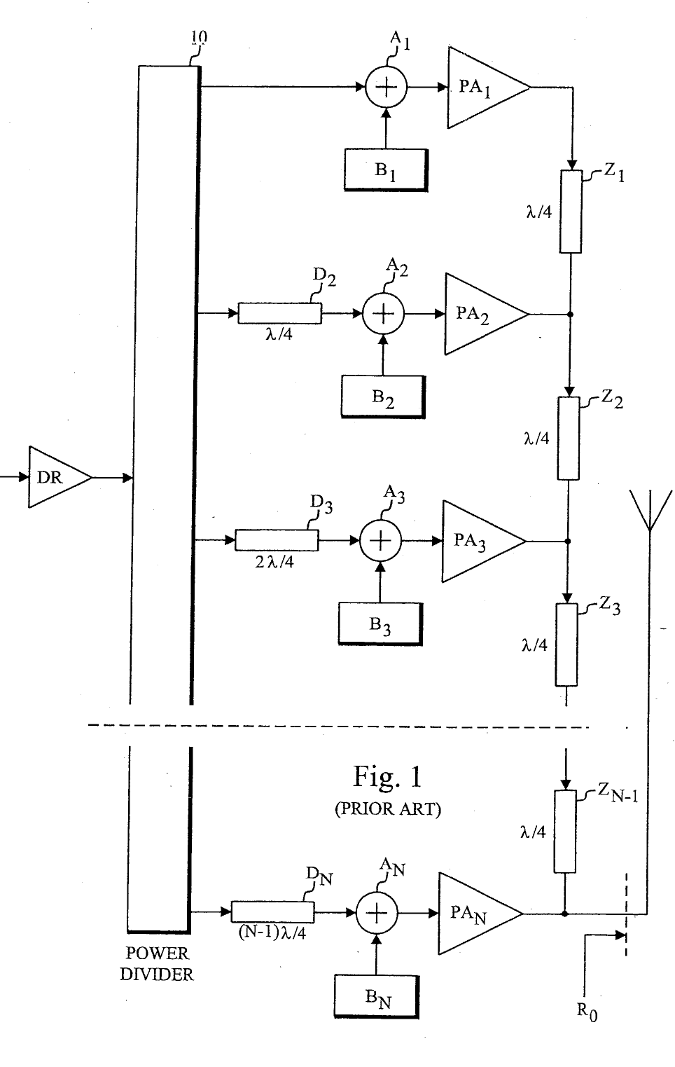

The general multistage Doherty amplifier as implemented in the prior art is shown in FIG. 1. In the following it is assumed that all amplifiers are made of identical transistors and have the same supply voltage V_{dd}. The amplifiers are assumed to be single-ended, but the same reasoning holds also for push-pull and other configurations. Some real-life effects such as transistor “knee” voltages, and finite output resistances, have also been disregarded in this simplified analysis.

In FIG. 1 a number of power amplifiers PA₁-PA_{N} are included in the different stages of a multistage Doherty amplifier. An input signal is forwarded to a common drive amplifier DR, for example a class B amplifier, and the output from the drive amplifier is forwarded to a power divider 10, which divides the signal into input signals for each stage. These signals generally have unequal power. Each stage, except the first, includes a delay element D₂-D_{N}. The delay increases by λ4 from stage to stage. Each stage also includes a bias mechanism represented by an adder A₁-A_{N} and a bias B₁-B_{N}. Typically this bias mechanism is implemented by a choke or quarter wave length transmission line connected to a bias voltage at one end and the power amplifier input line at the other end. The corresponding bias is added to the possibly delayed signal, and the resulting signal is forwarded to the corresponding power amplifier. On the output side the power amplifiers are interconnected by a Doherty output network including impedances Z₁-Z_{N}-₁, for example quarter wavelength transmission lines. Finally the Doherty amplifier is connected to a load R₀, for example an antenna. The bias level for a certain power amplifier, together with its share of the total input RF drive, sets the transition point for that specific amplifier. At output levels above this transition point the amplifier is active, otherwise it is shut off. Amplifier PA₁ is always active, so its transition point is zero. The transition points are chosen such that the average efficiency of the entire Doherty amplifier is maximized for the specific (statistical) signal amplitude distribution used. Above the respective transition points the amplifiers are active and operate as controlled current sources.

If the transition points (normalized to the maximum output voltage) for the amplifiers (except PA₁) are α₁, α₂, α₃, . . . , α_{N-1}, the characteristic impedances for the quarter wavelength transmission lines Z₁, Z₂, Z₃, . . . , Z_{N-1} are (for consistency, hereafter α_{N} is included with the value 1):

$${Z}_{k} = \frac{{R}_{0}}{{α}_{k} \cdot {α}_{k + 1}}$$

The effective transconductance of the transistors (amplifiers) is denoted gₘ. The RF currents delivered by a certain amplifier PAₖ above the transition points are increasing with increasing output voltage at a rate, “slope”, proportional to αₖ. The incremental current Δi for a desired increase in output voltage Δν for power amplifier PAₖ may be expressed as:

$$\frac{Δ i}{Δ v} = \frac{{α}_{k}}{{R}_{0}}$$

Counting backwards, the required incremental voltage drive Δν_{drive} is the current divided by the transconductance, i.e.:

$$\frac{Δ {v}_{drive}}{Δ v} = \frac{{α}_{k}}{{R}_{0} \cdot {g}_{m}}$$

If the input is assumed to be optimally matched, the transconductance can be related to the nominal (linear) power gain G of the amplifier. The gain is calculated with the “optimal” load resistance Rₒₚₜ that gives the maximum power iₘₐₓ * νₘₐₓ of the transistor. The Doherty amplifier is preferably constructed so that at least one of the transistors will deliver the peak current iₘₐₓ at peak power and therefore at peak output voltage. The optimal load resistance Rₒₚₜ for the transistor is thus νₘₐₓ/iₘₐₓ. The transconductance (assuming for simplicity that the input resistance of the transistor is also Rₒₚₜ or that the input is matched to Rₒₚₜ) may then be calculated as:

$${g}_{m} = \frac{\sqrt{G}}{{R}_{opt}}$$

However, the load resistance for the Doherty amplifier is different from the previously described optimum load resistance Rₒₚₜ, since several currents are fed to the same load. The relation between the optimum load resistance Rₒₚₜ for a single-transistor (class B) amplifier and the load resistance of the Doherty amplifier is:

R₀=Rₒₚₜ.(1−α_{N-1})

As seen in the preceding paragraphs, the required slope of the drive signal for a certain amplifier PAₖ is proportional to a transition point αₖ. We have several amplifier stages in a multistage Doherty amplifier, and the voltage drive for each amplifier in the Doherty compared to that of a single class B amplifier having the same maximum output voltage (but a different load resistance) is:

$$\frac{{v}_{drive}}{{v}_{driveB}} = \frac{{α}_{k}}{1 - {α}_{N - 1}}$$

The drive power scales as this value squared, and the sum of all the drive powers to all amplifiers can be quite substantial. The “top” stage power amplifier PA_{N} requires the most power, since α_{N} has the largest (normalized) value 1. This drive power compared to that of a class B amplifier, for an exemplary value of α_{N-1} of 0.5, is 4 times larger. To avoid having a too complicated drive amplifier, the drive power is, for example, produced by an ordinary class B amplifier. The low efficiency of the class B drive amplifier means that its DC power consumption will be high. This results in a high loss or equivalently low efficiency, of the total system including both the Doherty amplifier and the driver. The problem is especially pronounced if the power amplifiers in the Doherty amplifier have low gain.

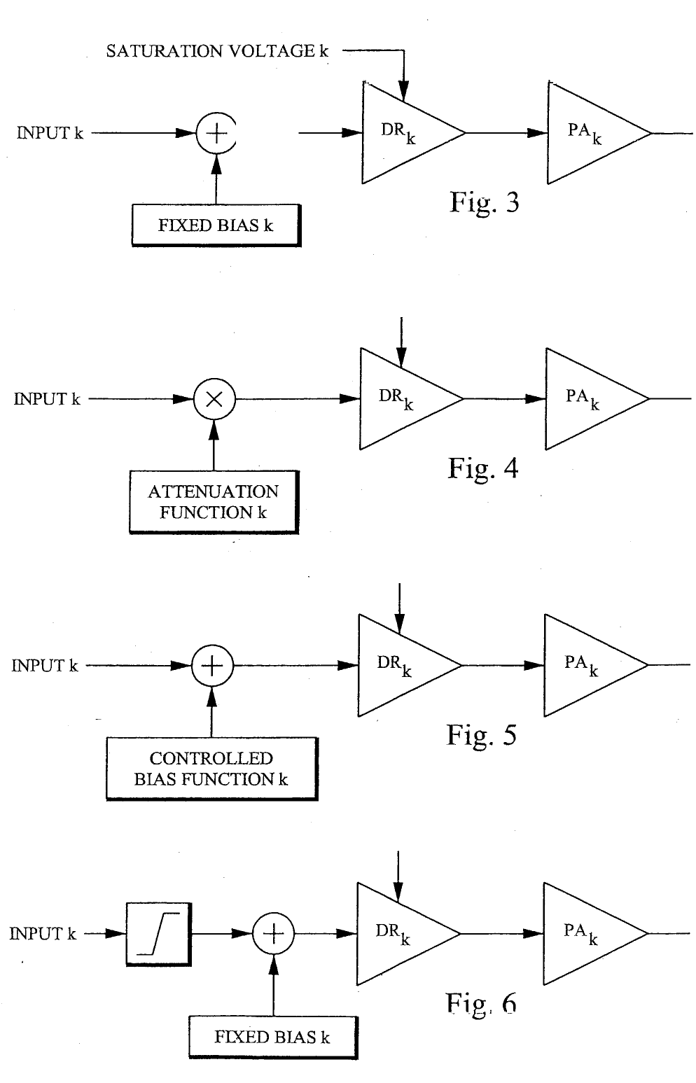

The poor linearity problem is caused by the fact that in the prior art multistage amplifiers, some of the amplifiers (all but the two top stages PA_{N} and PA_{N-1}) are required to saturate at certain transition points and remain saturated above these transition points. This is exemplified in FIG. 3 of [4] (and also in the text) and in section 7 of [1]. The latter example states that power amplifier PA₁ is saturated above a first transition point, the “medium power region”, and that power amplifier PA₂ and PA₁ are both saturated above a second transition point, the “high power region”, and act together as a single saturated power amplifier.

The problem with this implementation is that the first few amplifiers will be very deep into saturation for a large part of the output voltage range. The amplifiers will also frequently go very fast into deep saturation. In saturation, there is a huge problem with especially AM-PM distortion, which will manifest itself as reduced efficiency and increased distortion. The reduced efficiency is primarily caused by the non-optimal phase alignment between the different outputs, since the individual phases vary differently with the signal level. This non-optimal power combining also results in amplitude distortion.

A partial solution to the problem of excessive drive power for the “top” stages is proposed in [6] for conventional Doherty amplifiers. Here, a bias control reduces drive requirements. The same idea is also illustrated in FIG. 1 of [1], but is not discussed in the text. This solution possibly takes away the excessive slope requirement of the drive (by a factor of 1-α_{N-1}) for the topmost stages, but still consumes a lot of drive power (albeit lower than before) at all levels of output power. The mode of operation of the power amplifiers will also change over the output voltage range, from class C with small conduction angle towards class B.

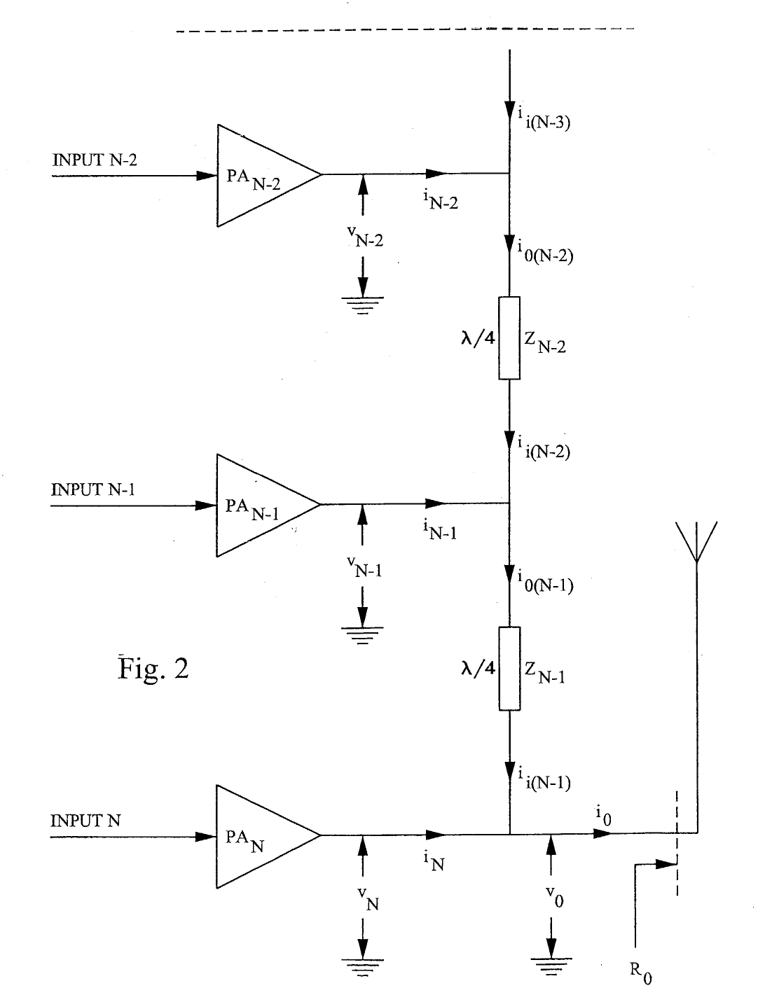

The multistage Doherty amplifier is a collection of RF amplifiers, acting as controlled current sources, connected by several impedance inverters. The currents and voltages present in some amplifier stages are shown in FIG. 2. For simplicity, the phases of the signals are assumed optimal and are neglected in the analysis. The general relations between the parameters are:

νₖ=i₀₍ₖ₋₁)·Zₖ₋₁

$${i}_{i ( k )} = \frac{{v}_{k}}{{Z}_{k}}$$

i₀₍ₖ₎=iₖ+iᵢ₍ₖ₋₁)

The solution starts with power amplifier PA₁, since i₀₍₁₎ is equal to its controlled current i₁. This makes it possible to calculate v₂, which can be used for solving iᵢ₍₂₎. Adding the controlled (and therefore known) current i₃ to iᵢ₍₂₎ gives i₀₍₃₎, which makes it possible to obtain v₄. This scheme is repeated until either the output voltage or current is obtained. The output current and voltage are related through Rₒ, which makes it possible from there to solve for the missing currents and voltages backwards towards PA₁. At this point all currents and voltages in the system are known. However, it is to be noted that this analysis reflects reality only for the ideal case where none of the amplifiers is saturated.

To achieve good efficiency, the drive amplifier for power amplifier PAₖ should ideally have zero output (or an output voltage that is below the bias level) and draw zero supply current below a first transition point αₖ₋₁. This gives a zero current output for the associated power amplifier in this region. The controlled current (and correspondingly the drive voltage) should then increase linearly from the first transition point to a second transition point αₖ₊₁, i.e. two transition points higher. From that point on, the current amplitude, and correspondingly the drive voltage, should be constant. By having these constant levels, instead of increasing the drive signals further as is done in the prior art, all the amplifiers in the Doherty amplifier can be held out of saturation. By proper choice of supply voltages for the drive amplifiers, or by having suitable transformation networks, they can have maximum efficiency throughout the entire constant-level region. The drive amplifiers in this arrangement also do not consume any power below their respective onset transition point.

The slope of the current vs. output voltage for power amplifier PAₖ in its linearly increasing region should be proportional to αₖ. The constant current levels may therefore be written as (for all but the two top amplifiers):

i_{const(k)} ∝αₖ·(αₖ₊₁−αₖ₋₁)

Here α₀ is included with the value 0. The drive voltages to the amplifiers for producing these currents are obtained by dividing the desired current function by gₘ. To create the correct drive voltages one can either let the drive amplifier saturate at the right point, use an attenuator or a multiplier with an attenuation function, create the signals digitally, use a variable bias drive amplifier or condition the signals with limiters.

Thus, the general idea of the present invention is to use a separate drive amplifier for each power amplifier, or separate drive amplifiers for groups of power amplifiers. This makes it possible to make significant improvements in efficiency and linearity by optimizing the drive for the different amplifiers and using only a minimum of drive power.

Solution to efficiency problem

The general solution to the efficiency problem is to let the drive amplifiers be active only when needed, and with as low voltage swing as possible. The drive amplifiers are then only active above the transition point of the associated power amplifier, and do not require the large extra swing associated with driving the Doherty amplifiers (deeply) in class C. Both aspects reduce the required drive power substantially and consequently increase efficiency greatly, especially when using low-gain amplifiers. The power amplifiers in the Doherty amplifier can be working as class B amplifiers.

A first implementation of this solution, which is illustrated in FIG. 3, is to use individually optimized class C amplifiers as drive amplifiers. The main idea here is to avoid using the Doherty power amplifiers for the signal conditioning, since this is both unnecessary and implies more (wasted) drive power. The signal conditioning is in this arrangement performed at the driver stages.

A second implementation is to pre-process the signals to class B or similar drive amplifiers. This can be done by the use of controlled attenuators before the drive amplifiers, as illustrated in FIG. 4, or by pre-drive stages that can be class C stages (possibly with controllable bias), as illustrated in FIG. 5. This increases efficiency in the same way as the previous solution, but the drive signals can be obtained in a more controllable manner.

### Solution to Linearity Problem

The general solution to the linearity problem is to avoid saturation in the Doherty amplifier. This is achieved by limiting the controlled currents for power amplifier PAₖ at the transition point associated with the onset of power amplifier PAₖ₊₂, a procedure that is necessary for all but the two top stages. The limiting of the controlled currents is done by limiting the output voltages from the drivers to constant levels above the transition points. The solution corrects for both distortion and the associated decreased power combining efficiency. It also reduces the required drive power and hence the DC power consumption of the driver.

A first implementation of this solution is to limit the drive amplifier voltages by letting the respective drive amplifier saturate, as illustrated in FIG. 3. This is a smaller problem than when the power amplifiers of the Doherty amplifier saturate, since the load impedance is constant for the drive amplifier and the parasitics are smaller.

A second implementation is to control the output voltages of the drive amplifiers by processing their inputs using variable attenuators or analog multipliers, as illustrated in FIG. 4.

A third implementation, which is illustrated in FIG. 5, is to use variable bias for the drive amplifiers. The bias level should then follow the increasing signal level to produce a constant output above the suitable transition point.

A fourth implementation, which is illustrated in FIG. 6, is to use limiters before or at the drive amplifiers.

The efficiency enhancements are generally most important for the topmost stages, since they consume most of the drive power in the prior art solutions. The solution to the linearity problem can be implemented for all but the two top stages. Consequently, the efficiency is generally not increased as much by this solution.

Based on the above discussion, a hybrid scheme, using individual drivers for the top (maybe two) amplifiers, and a single driver plus a power divider for the lower stages, can be devised. The signal conditioning for the lower stages could then be performed by limiters between the common drive amplifier and the respective power amplifier. A presently preferred implementation uses attenuators or analog multipliers for the modification of the drive signals, or creates the drive signals entirely in the digital domain. The implementation also uses one dedicated drive amplifier per power amplifier. In the example, a 5-stage Doherty amplifier is chosen that has been “hand-optimized” for a quasi-Rayleigh distributed signal with a 10-dB peak-to-average power ratio. The (normalized) transition points are as follows:

α₁=0.153

α₂=0.275

α₃=0.407

α₄=0.583

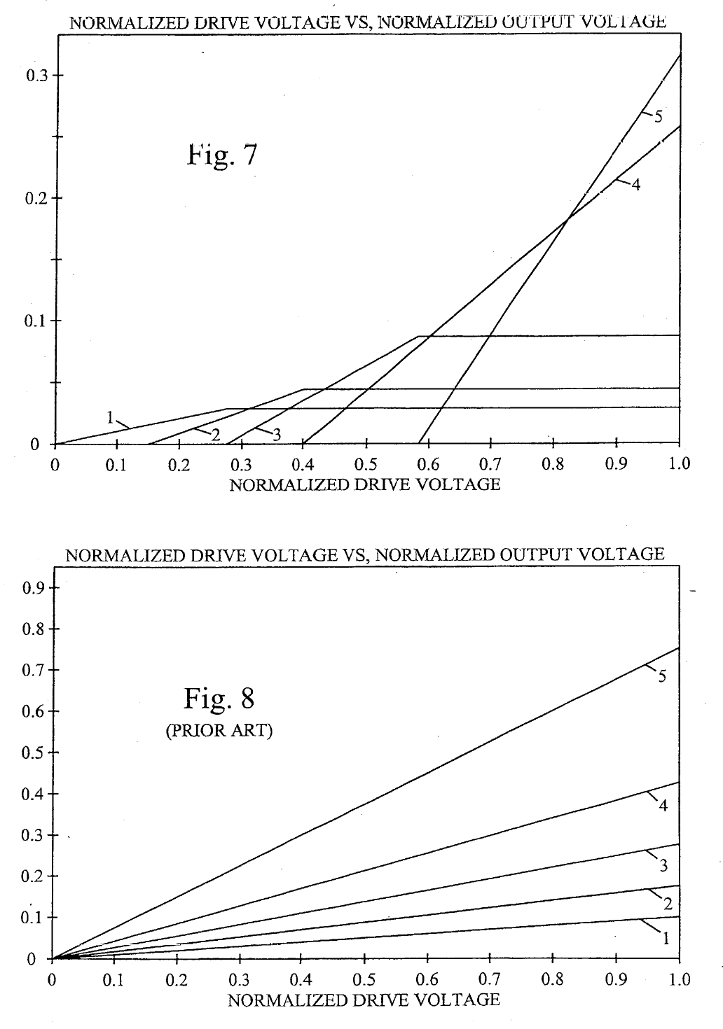

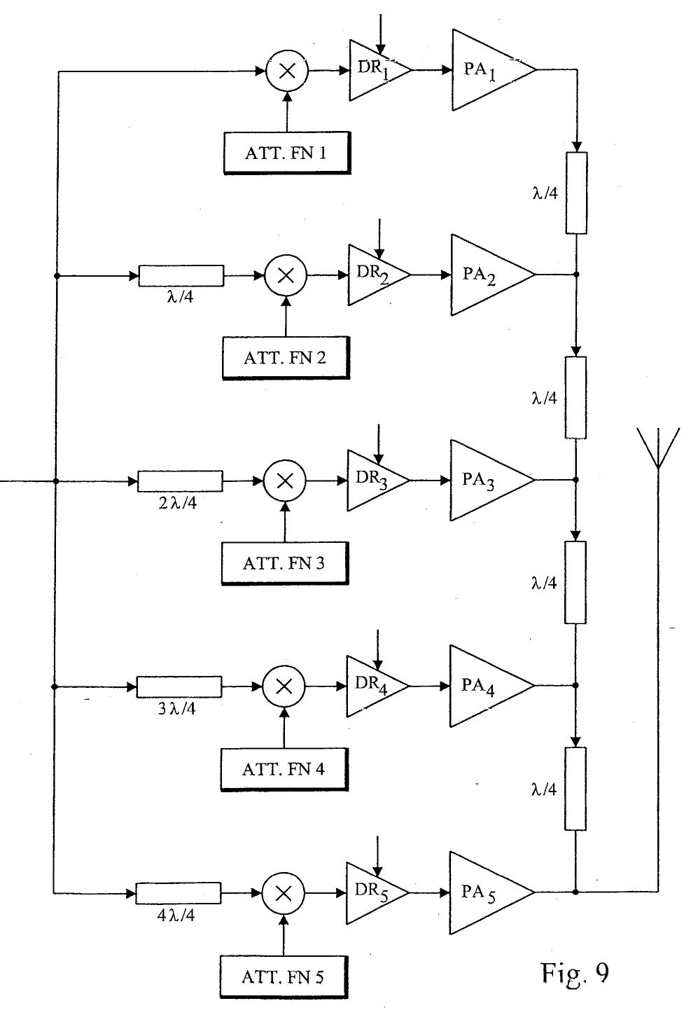

The (normalized) drive voltages vs. the (normalized) output voltage are shown in FIG. 7 (the stage numbers have been indicated in the figure). Here it is seen that the drive voltages that enter at higher transition points have a greater slope than those that enter at low transition points, and that the level is constant at output voltages beyond two transition points higher than the entry point. In the prior art solutions, the drive amplitudes have the same slope as in FIG. 7, but extend all the way from zero to maximum output voltage, as illustrated in FIG. 8 (it should be noted that the y-axis scales are different in FIG. 8 and 9). Consequently, the total amplitudes are much greater.

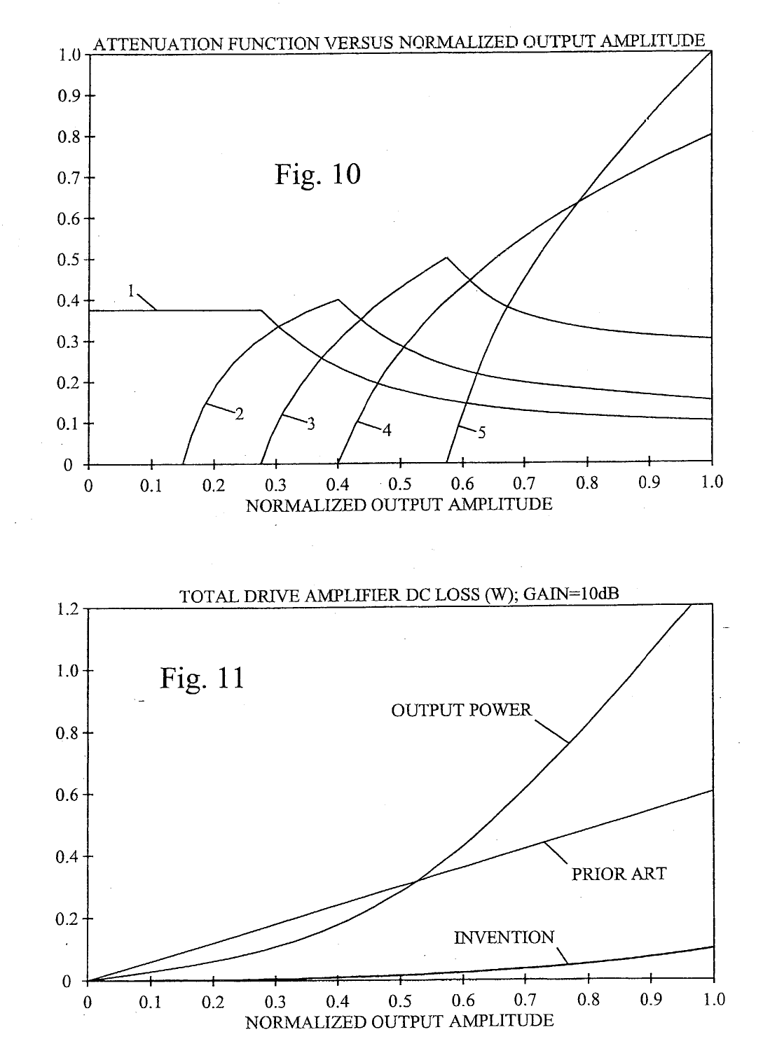

FIG. 9 illustrates an exemplary embodiment of the Doherty amplifier in accordance with the present invention. In FIG. 9 it is noted that the single shared drive amplifier DR in FIG. 1 has been replaced by individual drive amplifiers DR₁-DR₅. For obtaining the drive voltages, the RF signal can, according to one embodiment of the present invention, be multiplied by attenuation functions ATT. FN 1-5 that are functions of the RF signal envelope. The respective attenuation functions (or multiplicands) are shown in FIG. 10 as functions of the (normalized) RF envelope level. As indicated by the antenna the Doherty amplifier may be part of a transmitter, for example a transmitter in a base station in a cellular mobile radio communication system.

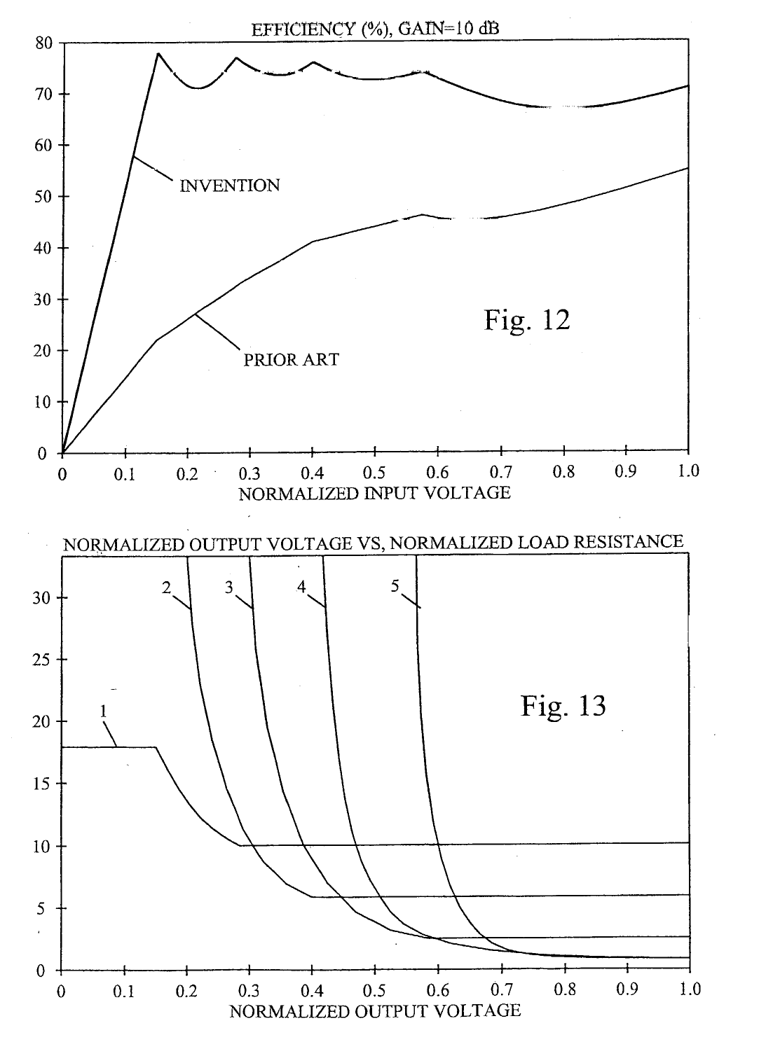

An example of the total DC power consumption (loss) of the drive amplifier for the prior art (single class B drive amplifier DR with power divider) solution and of the embodiment of the invention that is illustrated in FIG. 9, with individually optimized drive amplifiers for all power amplifiers DR₁-DR₅, is shown in FIG. 11. The gain of the amplifiers is 10 dB, and the output power of the Doherty amplifier is shown for reference. The high drive power required, and hence the high DC power (loss) in the single drive amplifier, reduces the efficiency due to the limited gain of the amplifiers. The corresponding loss is a lot less pronounced in the present invention, as can be seen from FIG. 12, which illustrates the efficiency as a function of output voltage. For the present invention the efficiency is mostly (and only slightly) degraded at high output levels. For the prior art the efficiency is severely impaired for all output levels.

Table 1 below compares the efficiency of the present invention to the efficiency of the prior art drive arrangement in FIG. 1. In order to set these numbers into perspective, the ideal 5-stage Doherty amplifier has an intrinsic efficiency of 75.6% for a quasi-Rayleigh distributed signal with a 10-dB peak-to-average power ratio. As can be seen from the table, most of this efficiency is retained by the present invention even at very low gains.

TABLE 1

| Gain | Class B drive | Invention |
|---|---|---|
| 30 dB | 74.8% | 75.6% |
| 20 dB | 68.6% | 75.4% |
| 17 dB | 62.8% | 75.2% |
| 13 dB | 50.0% | 74.5% |
| 10 dB | 37.4% | 73.5% |
| 6 dB | 21.2% | 70.7% |

The very high efficiency of the present invention is due to certain differences between the operation of a Doherty amplifier and conventional amplifiers.

Firstly, the nominal gain for the transistors in conventional amplifiers is calculated with an “optimal” load for achieving peak power for a single amplifier stage. The load for the amplifiers in the Doherty amplifier is actually much higher than this value most of the time, which means that the gains for the amplifiers are also higher than the nominal gain. These load resistances, normalized to the optimal load resistance, are shown in FIG. 13. For example, power amplifier PA₁ sees a load that goes from ˜18 down to ˜10 times the optimal load, and its gain is therefore also so much higher (about 20 dB at 10 times the optimal load). The power amplifiers therefore require much less drive power than expected.

Secondly, it is only the top amplifier PA₅ that ever sees the optimal load and consequently delivers its peak power. Additionally, the top amplifier only delivers a part (1-α₄) of the total power at this point. The rest of the power is delivered by amplifiers seeing a higher load, and consequently having higher gain, than the top amplifier.

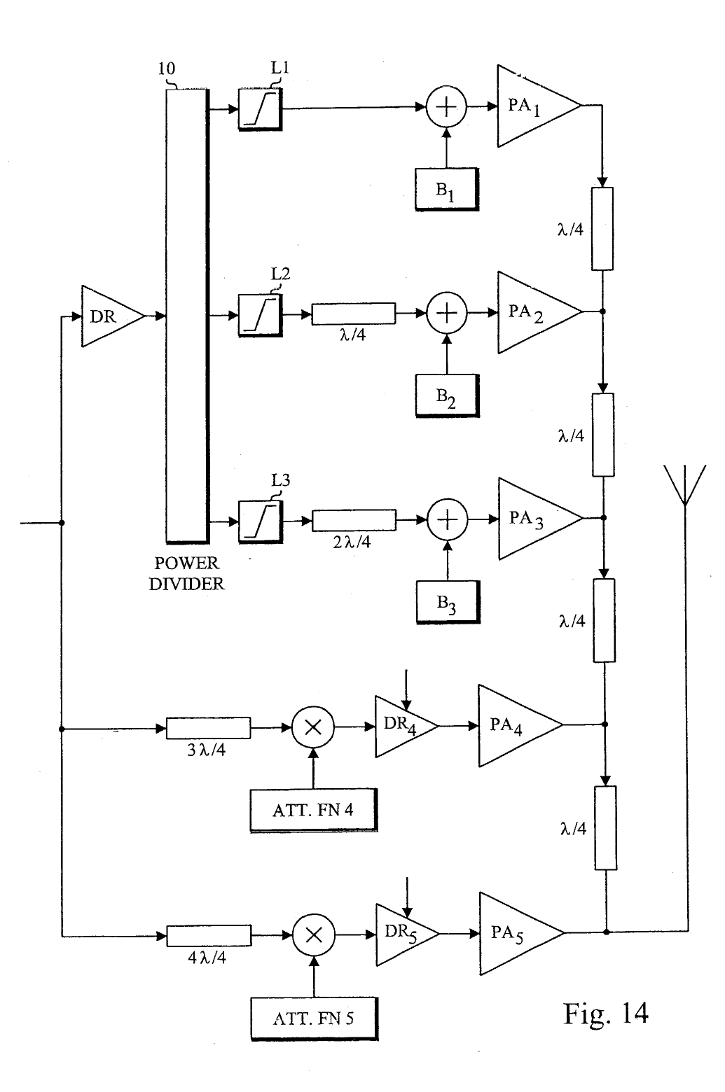

As noted above, a hybrid scheme using individual drivers for the top (maybe two) power amplifiers, and a single driver plus a power divider for the lower stages, can be devised. The signal conditioning for the lower stages could then be performed by limiters L1-L3 between the common drive amplifier and the respective power amplifier. Such an embodiment is illustrated in FIG. 14. The shared drive amplifier DR could be a class B amplifier. However, it is also possible to implement it as a Doherty amplifier to further increase efficiency.

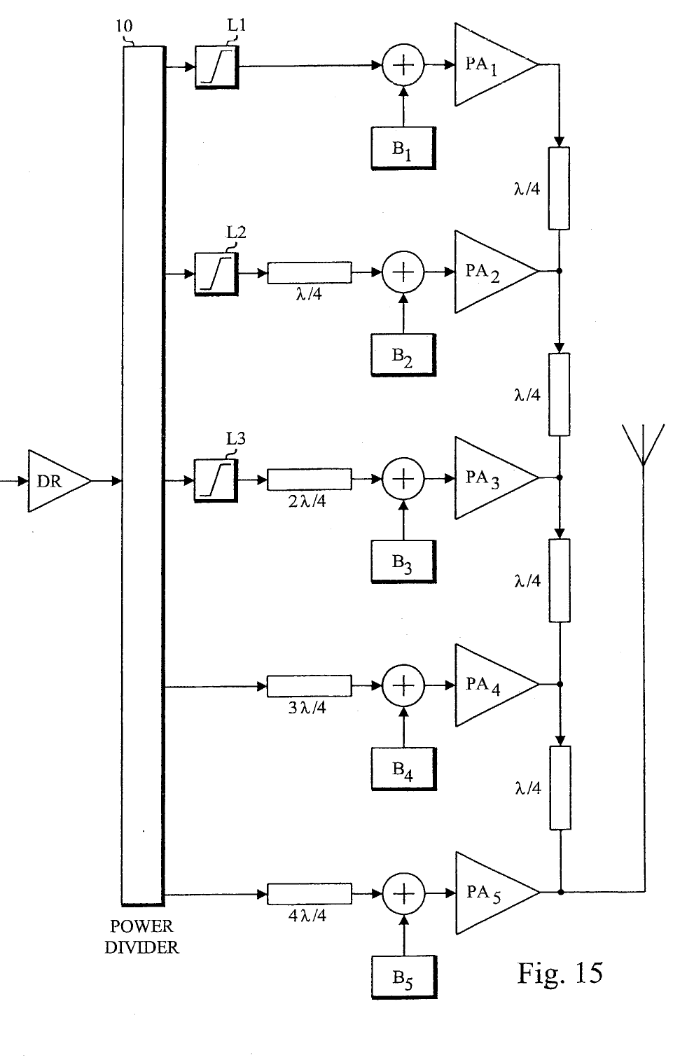

The concept of the embodiment of FIG. 14 may be extended even further to provide a very simple multistage Doherty amplifier. Thus, in the embodiment of FIG. 15 a shared drive amplifier DR and a power divider 10 are supplemented by individual voltage limiters L1-L3 for all but the two top stages. The shared drive amplifier DR could be a class B amplifier. However, it is also possible to implement it as a Doherty amplifier to further increase efficiency.

In the examples above the shared drive amplifier was in some embodiments implemented as a class B amplifier. However, it is also feasible to implement it as a class A or class AB amplifier.

It will be understood by those skilled in the art that various modifications and changes may be made to the present invention without departure from the scope thereof, which is defined by the appended claims.

### References

[1] F. H. Raab, “Efficiency of Doherty RF Power Amplifier Systems”, IEEE Trans. Broadcasting, vol. BC-33, no. 3, pp. 77-83, Sept. 1987.

[2] D. M. Upton et al., U.S. Pat. No. 5.420,541.

[3] J. J. Schuss et al., U.S. Pat. No. 5,568,086.

[4] B. E. Sigmon, U.S. Pat. No. 5,786,727.

[5] Y. Tajima et al., U.S. Pat. No. 5,025,225.

[6] J. E. Mitzlaff, WO 98/00912.

1. A multistage Doherty amplifier, including a plurality of drive amplifiers driving different stages.

2. The amplifier of claim 1, including individual drive amplifiers for at least some stages.

3. The amplifier of claim 1 or 2, wherein at least one drive amplifier is an individually optimized class C drive amplifier.

4. The amplifier of claim 1 or 2, wherein at least one drive amplifier is an amplifier with pre-processed input signal.

5. The amplifier of claim 4, including controllable attenuation means for preprocessing said input signal.

6. The amplifier of claim 1 or 2, including means for limiting drive amplifier input signal amplitude.

7. The amplifier of claim 1 or 2, including means for limiting drive amplifier output voltage.

8. The amplifier of claim 1 or 2, including means for variable attenuation of drive amplifier output voltage.

9. The amplifier of claim 1 or 2, including means for variable drive amplifier bias.

10. The amplifier of claim 1 or 2, including a shared drive amplifier for at least one group of stages.

11. The amplifier of claim 10, including a shared drive amplifier connected to a power divider, which is connected to a group of power amplifiers.

12. The amplifier of claim 10, including a shared Doherty drive amplifier connected to a power divider, which is connected to a group of power amplifiers.

13. A transmitter including a multistage Doherty amplifier, including a plurality of drive amplifiers driving different Doherty amplifier stages.

14. The transmitter of claim 13, including individual drive amplifiers for at least some stages.

15. The transmitter of claim 13 or 14, wherein at least one drive amplifier is an individually optimized class C drive amplifier.

16. The transmitter of claim 13 or 14, wherein at least one drive amplifier is an amplifier with pre-processed input signal.

17. The transmitter of claim 16, including controllable attenuation means for pre-processing said input signal.

18. The transmitter of claim 13 or 14, characterized by means for limiting drive amplifier input signal amplitude.

19. The transmitter of claim 13 or 14, including means for limiting drive amplifier output voltage.

20. The transmitter of claim 13 or 14, including means for variable attenuation of drive amplifier output voltage.

21. The transmitter of claim 13 or 14, including means for variable drive amplifier bias.

22. The transmitter of claim 13 or 14, including a shared drive amplifier for at least one group of stages.

23. The transmitter of claim 22, including a shared drive amplifier connected to a power divider, which is connected to a group of power amplifiers.

24. The transmitter of claim 22, including a shared Doherty drive amplifier connected to a power divider, which is connected to a group of power amplifiers.

25. A multistage Doherty amplifier including:
a drive amplifier shared by all stages;
a power divider for dividing drive power between the stages; and
an individual drive voltage limiter for at least one of the stages.

26. The amplifier of claim 25, including an individual drive voltage limiter for all but the two top stages.

27. A transmitter provided with a multistage Doherty amplifier, said Doherty amplifier including:
a drive amplifier shared by all stages;
a power divider for dividing drive power between the stages; and
an individual drive voltage limiter for at least one of the stages.

28. The transmitter of claim 27, including an individual drive voltage limiter for all but the two top stages.
